(19) United States
(12) Patent Application Publication
(10) Pub. No.: US 2025/0357694 A1
(43) Pub. Date: Nov. 20, 2025

(54) ELECTRICAL CONNECTOR

(71) Applicant: POINT ENGINEERING CO., LTD., Asan-si (KR)

(72) Inventors: Bum Mo AHN, Suwon-si (KR); Seung Ho PARK, Hwaseong-si (KR); Chang Hee HONG, Yongin-si (KR)

(73) Assignee: POINT ENGINEERING CO., LTD., Asan-si (KR)

(21) Appl. No.: 19/198,126

(22) Filed: May 5, 2025

(30) Foreign Application Priority Data
May 16, 2024 (KR) 10-2024-0063922

(51) Int. Cl. H01R 13/24; G01R 1/067; G01R 1/073; H01R 13/03; H01R 13/646

(52) U.S. Cl. CPC H01R 13/2492; G01R 1/06716; G01R 1/06733; G01R 1/06755; G01R 1/06772; G01R 1/07314; H01R 13/03; H01R 13/2407; H01R 13/2471; H01R 13/646; H01R 2201/20

(57) ABSTRACT

The present invention relates to an electrical connector comprising a first metal layer and a second metal layer, wherein the electrical connector comprises: a plurality of beam portions consisting of the first metal layer, wherein the second metal layer is not provided between the first metal layers in the thickness direction such that the first metal layers are spaced apart from each other in the thickness direction and elastically deformed by an external force applied in the length direction; and a connecting portion in which the first metal layer and the second metal layer are stacked in the thickness direction and which connects the plurality of beam portions, thereby providing an electrical connector with an increased surface area and improved current carrying capacity (CCC).

### CROSS-REFERENCE TO RELATED APPLICATIONS

The present application claims priority to Korean Patent Application No. 10-2024-0063922, filed May 16, 2024, the entire contents of which is incorporated herein for all purposes by this reference.

### TECHNICAL FIELD

The present invention relates to an electrical connector.

### BACKGROUND

In semiconductor devices, display panels, or cameras, continuity tests and operational characteristic tests are generally conducted during the manufacturing process. These tests are performed by connecting the electrode part of the object to be tested and the testing device using an electrical connector. The testing device is equipped with numerous electrical connectors, ranging from hundreds to hundreds of thousands, corresponding to the number of electrode parts of the object to be tested.

Electrical characteristic tests are conducted by bringing the object to be tested close to the testing device equipped with multiple electrical connectors and contacting the electrical connectors with the corresponding external terminals on the object to be tested. Recently, technologies for manufacturing electrical connectors using MEMS processes have been developed (for example, Korean Patent Publication No. 10-2024-0032783, Korean Patent Publication No. 10-2024-0017651).

Recently, the demand for testing high-frequency objects for AI and 5G applications has been increasing. In cases where high-frequency testing is required, the current carrying capacity (CCC) of the electrical connector needs to be large. To improve the current carrying capacity (CCC) of the electrical connector, a slit configuration penetrating the elastic part in the thickness direction is applied to the elastic part of the electrical connector. However, there are limitations in significantly improving the current carrying capacity (CCC) with slits penetrating only in the thickness direction. Additionally, there are limitations in reducing the pin force with slits penetrating only in the thickness direction.

Considering these points, there is a need to develop highly reliable electrical connectors for testing objects during the testing process.

### PRIOR ART DOCUMENTS

### Patent Documents

(Patent Document 1) Korean Patent Publication No. 10-2024-0032783
(Patent Document 2) Korean Patent Publication No. 10-2024-0017651
(Patent Document 3) Korean Patent No. 10-1082459
(Patent Document 4) Korean Patent No. 10-1906626
(Patent Document 5) Japanese Patent Publication No. 2012-173263

### SUMMARY

The present invention has been devised to solve the problems of the prior art described above, and its purpose is to provide an electrical connector with a significantly increased surface area, thereby having an improved current carrying capacity (CCC). Additionally, the present invention aims to provide a highly reliable electrical connector.

To achieve the aforementioned objectives, the electrical connector according to the present invention comprises a first metal layer and a second metal layer, wherein the electrical connector comprises: a plurality of beam portions consisting of the first metal layer, wherein the second metal layer is not provided between the first metal layers in the thickness direction such that the first metal layers are spaced apart from each other in the thickness direction and elastically deformed by an external force applied in the length direction; and a connecting portion in which the first metal layer and the second metal layer are stacked in the thickness direction and which connects the plurality of beam portions.

Additionally, the metal constituting the first metal layer is selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy or nickel-phosphorus (NiPh) alloy, nickel-manganese (NiMn), nickel-cobalt (NiCo) or nickel-tungsten (NiW) alloy, and the metal constituting the second metal layer is selected from copper (Cu), silver (Ag), gold (Au) or alloys thereof.

Additionally, the first metal layer is continuously formed in the length direction to constitute the connecting portion and the beam portion, and the second metal layer does not constitute the beam portion but constitutes the connecting portion 120.

Additionally, the spacing distance of the beam portions in the thickness direction is the same as the thickness of the second metal layer provided in the connecting portion.

Additionally, the beam portions are spaced apart in the width direction and the thickness direction to constitute a deformation portion array, and the connecting portion connects the beam portions of the deformation portion array.

Additionally, the connecting portion includes an upper connecting portion provided on the upper side of the deformation portion array, and the length dimension of the upper connecting portion in the width direction is larger than the length dimension of the deformation portion array in the width direction, and the length dimension of the upper connecting portion in the thickness direction is the same as the length dimension of the deformation portion array in the thickness direction.

Additionally, the connecting portion includes an upper connecting portion provided on the upper side of the deformation portion array, and the upper connecting portion is provided by alternately stacking the first metal layer and the second metal layer in the thickness direction.

Additionally, the lower part of the protruding portion of the upper connecting portion is a portion overlapping the upper surface of the guide plate, and the first metal layer is extended further downward than the second metal layer so that the second metal layer does not protrude from the lower part of the upper connecting portion.

Additionally, the connecting portion includes an upper connecting portion provided on the upper side of the deformation portion array, the electrical connector includes an upper tip portion provided on the upper side of the upper connecting portion, and the upper tip portion is not provided with the second metal layer such that each is spaced apart from each other in the thickness direction.

Additionally, the connecting portion includes an upper connecting portion provided on the upper side of the deformation portion array, the electrical connector includes an upper tip portion provided on the upper side of the upper connecting portion, and the first metal layer and the second metal layer of the upper connecting portion are extended and provided in the upper tip portion.

Additionally, the connecting portion includes a lower connecting portion provided on the upper side of the deformation portion array, and the lower connecting portion is provided by stacking the first metal layer and the second metal layer in the thickness direction.

Additionally, the connecting portion includes a lower connecting portion provided on the upper side of the deformation portion array, the electrical connector includes a lower tip portion provided on the lower side of the lower connecting portion, and the lower tip portion is not provided with the second metal layer such that each is spaced apart from each other in the thickness direction.

Additionally, the connecting portion includes a lower connecting portion provided on the upper side of the deformation portion array, the electrical connector includes a lower tip portion provided on the lower side of the lower connecting portion, and the first metal layer and the second metal layer of the lower connecting portion are extended and provided in the lower tip portion.

Additionally, a slit is provided between the beam portions in the width direction, and the slit is recessed inward of the connecting portion, and the length of the slit in the length direction is longer than the length of the beam portion in the length direction.

The present invention provides an electrical connector with a significantly increased surface area, resulting in an improved current carrying capacity (CCC).

Additionally, the present invention offers a highly reliable electrical connector.

Furthermore, the present invention can be more effectively utilized for inspecting high-frequency test objects for AI and 5G applications.

### BRIEF DESCRIPTION OF DRAWINGS

The above and other features of embodiments of the disclosure will become apparent by describing in detail embodiments thereof with reference to the accompanying drawings.

FIG. 1 is a perspective view of an electrical connector according to a preferred first embodiment of the present invention.

FIG. 2 is a front view of an electrical connector according to a preferred first embodiment of the present invention.

FIG. 3 is a side view of an electrical connector according to a preferred first embodiment of the present invention.

FIG. 4 is a top perspective view of an electrical connector according to a preferred first embodiment of the present invention.

FIG. 5 is a rear view of an electrical connector according to a preferred first embodiment of the present invention.

FIG. 6 is a cross-sectional view taken along line A-A′ of FIG. 2.

FIG. 7 is a cross-sectional view taken along line B-B′ of FIG. 2.

FIG. 8 is a cross-sectional perspective view taken along line C-C′ of FIG. 2.

FIG. 9 is an exploded perspective view of an electrical connector according to a preferred first embodiment of the present invention.

FIG. 10 is a perspective view of an electrical connector according to a modified example of the first embodiment.

FIG. 11 is an exploded view of an electrical connector according to a modified example of the first embodiment.

FIG. 12 is a perspective view of an electrical connector according to a preferred second embodiment of the present invention.

FIG. 13 is a perspective view of an electrical connector according to a preferred third embodiment of the present invention.

FIG. 14 is a perspective view of an electrical connector according to a preferred fourth embodiment of the present invention.

FIG. 15 is a perspective view of an electrical connector according to a preferred fifth embodiment of the present invention.

FIG. 16 is a perspective view of an electrical connector according to a preferred sixth embodiment of the present invention.

FIG. 17 is a perspective view of an electrical connector according to a preferred seventh embodiment of the present invention.

FIG. 18 is a perspective view of an electrical connector according to a preferred eighth embodiment of the present invention.

FIG. 19 is a perspective view of an electrical connector according to a preferred ninth embodiment of the present invention.

FIG. 20 is a perspective view of an electrical connector according to a preferred tenth embodiment of the present invention.

FIG. 21 is a perspective view of an electrical connector according to a preferred eleventh embodiment of the present invention.

### DETAILED DESCRIPTION OF THE EMBODIMENTS

The following content merely illustrates the principles of the invention. Therefore, those skilled in the art can devise various devices that implement the principles of the invention and are included within the concept and scope of the invention, even if they are not explicitly described or shown in this specification. Additionally, all conditional terms and embodiments listed in this specification are intended, in principle, solely for the purpose of understanding the concept of the invention and should not be understood as being limited to the specifically listed embodiments and conditions.

The above-mentioned objectives, features, and advantages will become more apparent from the following detailed description in conjunction with the accompanying drawings, and thus, those skilled in the art can easily implement the technical idea of the invention.

The embodiments described in this specification will be explained with reference to the ideal exemplary cross-sectional and/or perspective views of the invention. The thicknesses of the films and regions shown in these drawings are exaggerated for effective explanation of the technical content. The shapes in the exemplary drawings may be modified due to manufacturing techniques and/or tolerances. Also, the number of structures shown in the drawings is illustrative and only a part of them is shown. Therefore, the embodiments of the invention are not limited to the specific forms shown but include variations in form generated according to the manufacturing process.

Hereinafter, the preferred embodiments of the present invention will be described in detail with reference to the accompanying drawings.

An electrical connector 100 according to a preferred embodiment of the present invention can be used to transmit electrical signals by being mounted on a test device and electrically and physically connecting to a test object.

The test object includes, but is not limited to, electronic devices or components such as semiconductor devices, display panels, or cameras. For example, the test object may include memory chips, microprocessor chips, logic chips, light-emitting devices, substrates, or combinations thereof. At least one of the test objects may include logic LSI (such as ASIC, FPGA, and ASSP), microprocessors (such as CPU and GPU), memory (such as DRAM, HMC (Hybrid Memory Cube), MRAM (Magnetic RAM), PCM (Phase-Change Memory), ReRAM (Resistive RAM), FeRAM (Ferroelectric RAM), and flash memory (NAND flash)), semiconductor light-emitting devices (including LED, mini LED, micro LED, etc.), power devices, analog ICs (such as DC-AC converters and insulated gate bipolar transistors (IGBT)), MEMS (such as accelerometers, pressure sensors, vibrators, and gyro sensors), wireless devices (such as GPS, FM, NFC, RFEM, MMIC, and WLAN), discrete devices, BSI, CIS, camera modules, CMOS, passive devices, GAW filters, RF filters, RF IPD, APE, and BB. Additionally, the test object may be in the form of a semiconductor wafer or a packaged semiconductor device.

In the following description, the width direction of the electrical connector 100 is the ±x direction indicated in the drawings, the length direction of the electrical connector 100 is the ±y direction indicated in the drawings, and the thickness direction of the electrical connector 100 is the ±z direction indicated in the drawings.

### Electrical Connector 100 According to the First Embodiment

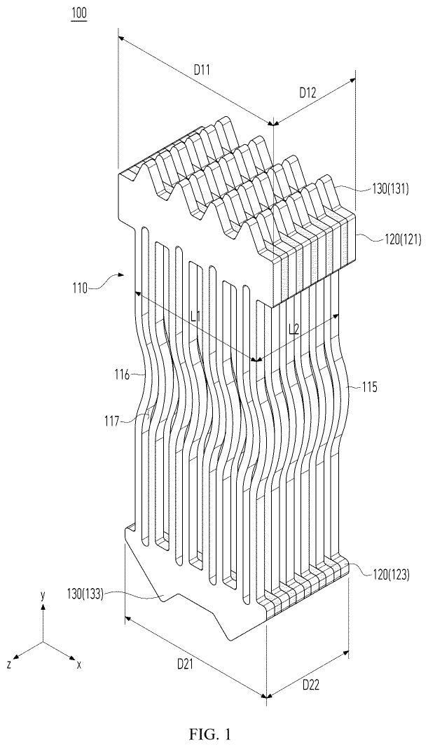

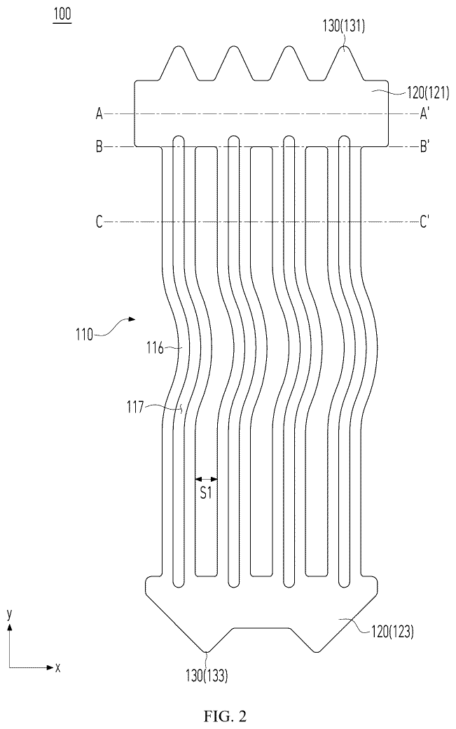

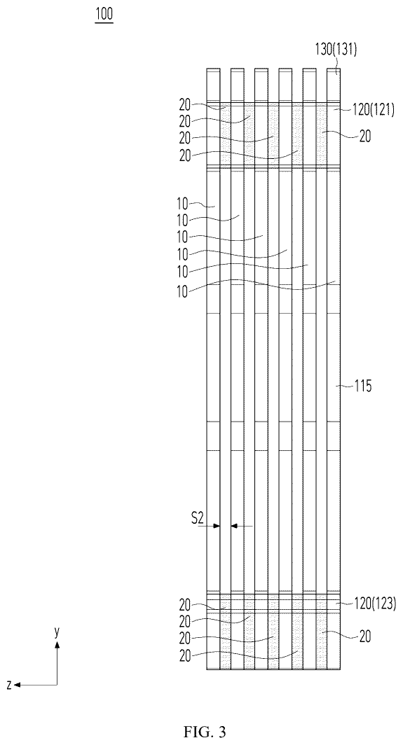

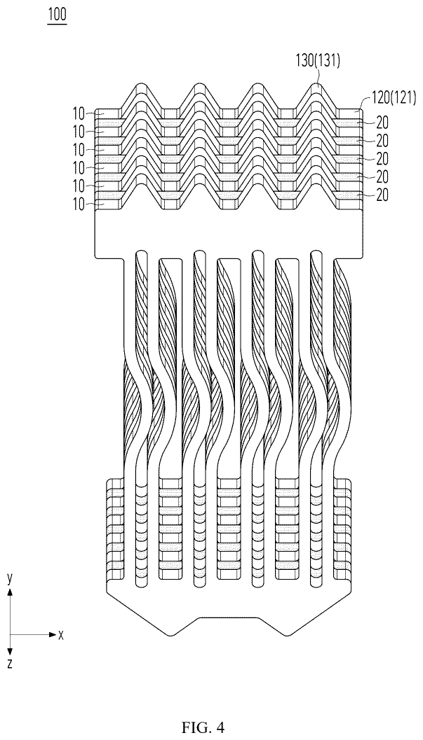

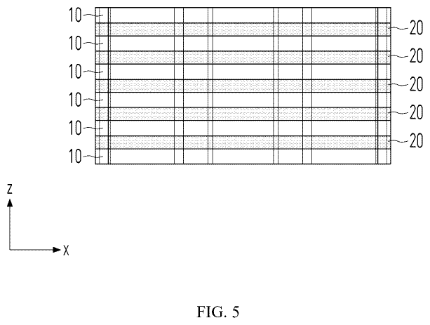

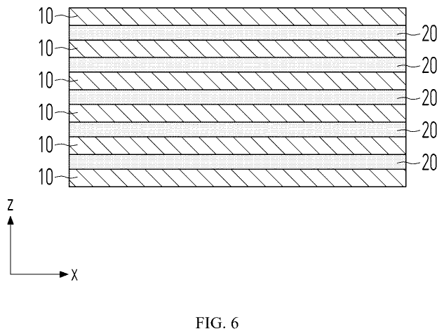

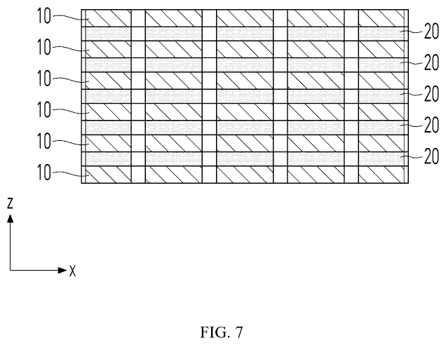

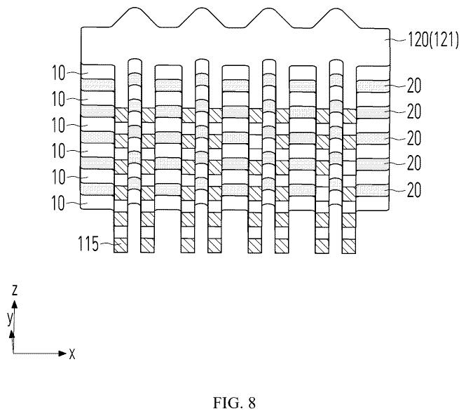

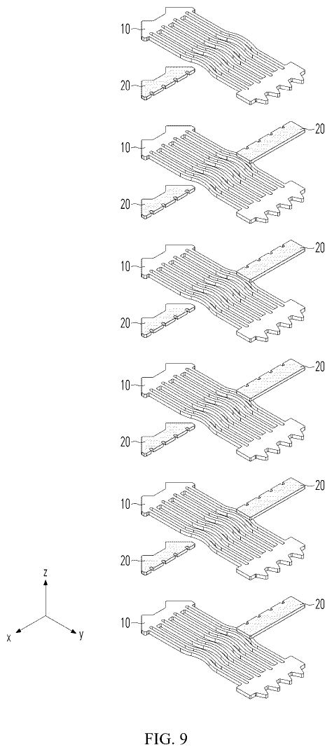

FIG. 1 is a perspective view of an electrical connector 100 according to a preferred first embodiment of the present invention, FIG. 2 is a front view of the electrical connector 100 according to a preferred first embodiment of the present invention, FIG. 3 is a side view of the electrical connector 100 according to a preferred first embodiment of the present invention, FIG. 4 is a top perspective view of the electrical connector 100 according to a preferred first embodiment of the present invention, FIG. 5 is a rear view of the electrical connector 100 according to a preferred first embodiment of the present invention, FIG. 6 is a cross-sectional view of the A-A′ portion of FIG. 2, FIG. 7 is a cross-sectional view of the B-B′ portion of FIG. 2, FIG. 8 is a cross-sectional perspective view of the C-C′ portion of FIG. 2, and FIG. 9 is an exploded perspective view of the electrical connector 100 according to a preferred first embodiment of the present invention.

The electrical connector 100 comprises a deformation portion array 110 and a connecting portion 120.

The deformation portion array 110 includes a plurality of beam portions 115 that extend in the length direction (±y direction) and are elastically deformed. The deformation portion array 110 is configured by arranging multiple beam portions 115 with small cross-sectional areas in an array form, spaced apart from each other. The beam portions 115 are spaced apart in at least one of the width direction (±x direction) and the thickness direction (±z direction) to constitute the deformation portion array 110.

The connecting portion 120 connects the beam portions 115 constituting the deformation portion array 110. A plurality of beam portions 115 are connected to a single connecting portion 120. The plurality of beam portions 115 provided in a bundle form are connected to the connecting portion 120 while being spaced apart from each other and integrated. The plurality of beam portions 115 are connected to the connecting portion 120, and each beam portion 115 is provided in a spaced-apart form, so the plurality of beam portions 115 are bundled through the connecting portion 120. The connecting portion 120 fixes the plurality of beam portions 115 to be spaced apart from each other and allows the plurality of beam portions 115 to move together.

Since the deformation portion array 110 is composed of a plurality of beam portions 115 that are spaced apart and divided, it can reduce the pin force of the deformation portion array 110 and significantly improve the overall surface area.

The shapes of all the beam portions 115 constituting the deformation portion array 110 are the same. Through the configuration of the beam portions 115 having the same shape, the external pressing force is uniformly dispersed. Each beam portion 115 extends in the length direction (±y direction) and has a bent portion 116 formed in the middle. The bent portion 116 is in a ‘C’ shape or an inverted ‘C’ shape. Each beam portion 115 is elastically deformed by an external force applied in the length direction (±y direction).

The cross-section of the beam portion 115 in the x-z plane is rectangular.

The beam portions 115 are spaced apart in the width direction (±x direction) and provided in plurality. Additionally, the beam portions 115 are spaced apart in the thickness direction (±z direction) perpendicular to the width direction (±x direction) and provided in plurality. Thus, the beam portions 115 are spaced apart in the width direction (±x direction) and the thickness direction (±z direction) and provided in plurality to constitute the deformation portion array 110.

The plurality of beam portions 115 are spaced apart from each other by a second spacing gap S2 in the thickness direction (±z direction). The deformation portion array 110 is provided with a plurality of beam portions 115 spaced apart from each other by a first spacing gap S1 in the width direction (±x direction) and spaced apart from each other by a second spacing gap S2 in the thickness direction (±z direction) perpendicular to the width direction (±x direction). The sizes of the first spacing gap S1 and the second spacing gap S2 may be the same or different.

The length dimension of each beam portion 115 in the width direction (±x direction) is smaller than the length dimension in the thickness direction (±z direction), and since each beam portion 115 has a bent portion 116 bent in the same direction, it is more easily elastically deformed when subjected to compressive force in the length direction (±y direction).

The connecting portion 120 includes an upper connecting portion 121 provided on the upper side of the deformation portion array 110 and a lower connecting portion 123 provided on the lower side of the deformation portion array 110. One end of each beam portion 115 is connected to the upper connecting portion 121, and the other end of each beam portion 115 is connected to the lower connecting portion 123.

The tip portion 130 includes an upper tip portion 131 provided on the upper side of the upper connecting portion 121 and a lower tip portion 133 provided on the lower side of the lower connecting portion 123.

The upper surface of the upper connecting portion 121 is provided as a rectangular plane, and the upper tip portion 131 is provided to protrude on the rectangular plane of the upper connecting portion 121. The upper tip portion 131 is provided in plurality, spaced apart in the width direction (±x direction) and the thickness direction (±z direction), and makes multi-contact with the test object. The upper tip portion 131 is provided in plurality in the width direction (±x direction) and spaced apart in the thickness direction (±z direction) at the same position in the width direction (±x direction).

The upper tip portion 131 includes a base portion continuous with the upper connecting portion 121 and a needle portion located above the base portion with a smaller cross-sectional area than the base portion. The needle portion is the part that contacts the external terminal of the test object, and the base portion is the part that ensures the rigidity of the needle portion.

The lower tip portion 133 is provided in a corrugated shape in the width direction (±x direction) and the corrugated shape extends in the thickness direction (±z direction).

The beam portion 115 is provided with a slit 117. The slit 117 is provided between the beam portions 115 in the width direction (±x direction). The slit 117 penetrates the beam portion 115 in the thickness direction (±z direction).

As shown in the drawings, a total of four slits 117 are provided, and beam portions 115 are provided on the left and right sides in the width direction (±x direction) based on each slit 117. A total of four pairs of beam portions 115 are provided based on each slit 117, and a first spacing gap S1 is provided between each pair of beam portions 115. That is, each pair of beam portions 115 is spaced apart by the first spacing gap S1 in the width direction (±x direction). More specifically, in the width direction (±x direction), the beam portion 115, the slit 117, the beam portion 115, the first spacing gap S1, the beam portion 115, the slit 117, the beam portion 115, the first spacing gap S1, the beam portion 115, the slit 117, the beam portion 115, the first spacing gap S1, the beam portion 115, the slit 117, and the beam portion 115 may be positioned in this order.

The slit 117 is recessed inward of the connecting portion 120 in the length direction (±y direction). More specifically, the slit 117 is recessed inward in the length direction (±y direction) of at least one of the upper connecting portion 121 and the lower connecting portion 123. Preferably, one end of the slit 117 extends inward of the upper connecting portion 121 and is recessed inward of the upper connecting portion 121, and the other end of the slit 117 extends inward of the lower connecting portion 123 and is recessed inward of the lower connecting portion 123. On the other hand, one end of the beam portion 115 is connected to the lower surface of the upper connecting portion 121, and the other end of the beam portion 115 is connected to the upper surface of the lower connecting portion 123. As such, the slit 117 is recessed inward in the length direction (±y direction) of the connecting portion 120, and the length of the slit 117 in the length direction (±y direction) is longer than the length of the beam portion 115 in the length direction (±y direction). As the slit 117 is recessed inward of the connecting portion 120, it can minimize the concentration of stress at the root of the beam portion 115 by alleviating the abrupt change in area at the root of the beam portion 115.

The electrical connector 100 comprises a first metal layer 10 and a second metal layer 20. The first metal layer 10 and the second metal layer 20 are formed by being stacked in the thickness direction (±z direction) through a plating process in at least some areas.

The first metal layer 10 and the second metal layer 20 are made of different metal materials. The first metal layer 10 and the second metal layer 20 are provided in the form of flat plates with a certain thickness in the thickness direction (±z direction) and a flat plate shape in the x-y plane.

The metal constituting the first metal layer 10 is a metal with high wear resistance or rigidity, preferably selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, nickel-phosphorus (NiPh) alloy, nickel-manganese (NiMn), nickel-cobalt (NiCo) or nickel-tungsten (NiW) alloy. However, it is not limited to this. When a plurality of first metal layers 10 are provided, the material of each first metal layer 10 may be of the same or different materials. For example, a plurality of first metal layers 10 may be composed of the same material of palladium-cobalt (PdCo) alloy, or a plurality of first metal layers 10 may be formed of at least some palladium-cobalt (PdCo) alloy and the rest of nickel-cobalt (NiCo) alloy.

The metal constituting the second metal layer 20 is a metal with high electrical conductivity, preferably selected from copper (Cu), silver (Ag), gold (Au) or alloys thereof. However, it is not limited to this. When a plurality of second metal layers 20 are provided, the material of each second metal layer 20 may be of the same or different materials. For example, a plurality of second metal layers 20 may be composed of the same material of copper (Cu), or a plurality of second metal layers 20 may be formed of at least some copper (Cu) and the rest of gold (Au).

A second metal layer 20 in the form of a flat plate is provided between the first metal layers 10 in the form of a flat plate. The first metal layers 10 provided in a flat form have the same shape, and the second metal layers 20 provided in a flat form also have the same shape.

The first metal layer 10 provided in the form of a flat plate is formed of a metal with high wear resistance or rigidity, contributing to securing the wear resistance or rigidity of the electrical connector 100. In addition, by integrating the adjacent two first metal layers 10 in the thickness direction (±z direction) with a second metal layer 20 with relatively high electrical conductivity, the current carrying capacity (CCC) can be improved, and at the same time, it contributes to spacing the beam portions 115 apart in the thickness direction (±z direction).

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by alternately stacking the first metal layer 10 and the second metal layer 20 in the thickness direction (±z direction). The second metal layer 20 provided in the connecting portion 120 is provided between the adjacent first metal layers 10. An even number of first metal layers 10 and an odd number of second metal layers 20 may be provided. For example, as shown in the drawings, six first metal layers 10 may be provided in the thickness direction (±z direction) and five second metal layers 20 may be provided. However, the number of such stacks is not limited to this.

The second metal layer 20 is provided in the upper connecting portion 121 and the lower connecting portion 123. The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20, so each is spaced apart in the thickness direction (±z direction). On the other hand, the lower tip portion 133 is provided by extending the first metal layer 10 and the second metal layer 20 of the lower connecting portion 123, and the first metal layer 10 and the second metal layer 20 are stacked in the thickness direction (±z direction). However, it is not limited to this, and the upper tip portion 131 may also be provided by extending the first metal layer 10 and the second metal layer 20 of the upper connecting portion 121 and stacking the first metal layer 10 and the second metal layer 20 in the thickness direction (±z direction). In addition, the lower tip portion 133 may also be provided without the second metal layer 20, so each is spaced apart in the thickness direction (±z direction).

The second metal layer 20 provided in the upper connecting portion 121 is provided in a shape corresponding to the shape of the first metal layer 10 provided in the upper connecting portion 121. The second metal layer 20 provided in the lower connecting portion 123 is provided in a shape corresponding to the shape of the first metal layer 10 provided in the lower connecting portion 121 and the lower tip portion 133.

The beam portion 115 consists of the first metal layer 10, and the second metal layer 20 is not provided between the first metal layers 10 in the thickness direction (±z direction), so the first metal layers 10 are spaced apart in the thickness direction (±z direction) and elastically deformed by an external force applied in the length direction.

The second spacing gap S2 between the beam portions 115 in the thickness direction (±z direction) is the same as the thickness of the second metal layer 20 provided in the connecting portion 120. Since the thickness of the second metal layer 20 provided in the connecting portion 120 is the same as the spacing distance of the beam portions 115 in the thickness direction (±z direction), the thickness of the second metal layer 20 provided in the connecting portion 120 determines the spacing distance of the beam portions 115 in the thickness direction (±z direction).

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by an applied force, it can maintain high strength, and the upper connecting portion 121 and the lower connecting portion 123 consist of the first metal layer 10 and the second metal layer 20, so the electrical conductivity of the upper connecting portion 121 and the lower connecting portion 123 can be improved.

The length dimension D11 of the upper connecting portion 121 in the width direction (±x direction) is larger than the length dimension L1 of the deformation portion array 110 in the width direction (±x direction). Meanwhile, the length dimension D12 of the upper connecting portion 121 in the thickness direction (±z direction) is the same as the length dimension L2 of the deformation portion array 110 in the thickness direction (±z direction). As a result, the length dimension D11 of the upper connecting portion 121 in the width direction (±x direction) is larger than the length dimension L1 of the deformation portion array 110 in the width direction (±x direction), and the length dimension D12 of the upper connecting portion 121 in the thickness direction (±z direction) is the same as the length dimension L2 of the deformation portion array 110 in the thickness direction (±z direction). Meanwhile, the length dimension D21 of the lower connecting portion 123 in the width direction (±x direction) is smaller than the length dimension D11 of the upper connecting portion 121 in the width direction (±x direction), and the length dimension D22 of the lower connecting portion 123 in the thickness direction (±z direction) is the same as the length dimension D12 of the upper connecting portion 121 in the thickness direction (±z direction). Under these numerical conditions, the upper connecting portion 121 can be easily installed on the guide plate of the inspection device by being caught in the guide hole of the guide plate in the portion protruding in the width direction (±x direction) beyond the deformation portion array 110.

The second metal layer 20 provided in the upper connecting portion 121 may be smaller in area than the first metal layer 10 provided in the upper connecting portion 121. In other words, at least a part of the second metal layer 20 provided in the upper connecting portion 121 may be recessed without protruding from the side of the upper connecting portion 121. Meanwhile, the second metal layer 20 provided in the lower connecting portion 123 may be smaller in area than the first metal layer 10 provided in the lower connecting portion 121 and the lower tip portion 1343. In other words, at least a part of the second metal layer 20 provided in the lower connecting portion 123 may be recessed without protruding from the side of the lower connecting portion 123.

The lower part of the protruding portion of the upper connecting portion 121 is a portion overlapping the upper surface of the guide plate, and if the second metal layer 20 directly contacts the upper surface of the guide plate, foreign substances may fall off from the second metal layer 20, which is relatively less rigid. Therefore, it is desirable to prevent the second metal layer 20 from protruding below the upper connecting portion 121. To this end, it is preferable that the first metal layer 10 extends further downward than the second metal layer 20 so that only the first metal layer 10 contacts the upper surface of the guide plate.

A subsequent plating layer (not shown) is formed on the surface of the electrical connector 100. The subsequent plating layer is formed conformally along the surface of the electrical connector 100. The subsequent plating layer is preferably formed of a metal with high electrical conductivity, such as copper (Cu), silver (Ag), gold (Au), or an alloy thereof. However, it is not limited to this. Preferably, it can be formed of gold (Au).

Conventionally, the elastically deformable portion was composed of a single beam portion with a large cross-sectional area, connected to the upper and lower contact portions. However, according to a preferred embodiment of the present invention, instead of a single beam portion, multiple beam portions 115 with smaller cross-sectional areas are arranged in an array. In other words, a preferred embodiment of the present invention adopts a configuration in which multiple beam portions 115 are arranged in a bundled state by the connecting portion 120.

According to an embodiment of the present invention, by arranging multiple beam portions 115 with smaller cross-sectional areas in an array instead of a single beam portion with a large cross-sectional area, the surface area of the electrical connector 100 is significantly increased. Additionally, since the entire surface of the electrical connector 100 is coated with a subsequent plating layer with high electrical conductivity, a preferred embodiment of the present invention provides an electrical connector 100 with improved current carrying capacity (CCC) compared to the prior art. Therefore, it can more effectively respond to high-frequency characteristic tests above the GHz range. Thus, the electrical connector 100 according to a preferred embodiment of the present invention can be more effectively used for testing high-frequency inspection objects for AI and 5G applications.

Furthermore, according to an embodiment of the present invention, by arranging multiple beam portions 115 with smaller cross-sectional areas in an array instead of a single beam portion with a large cross-sectional area, the pin force can be significantly reduced. Reducing the length dimension of the beam portion 115 in the width direction (±x direction) can lower the pin force, but this may cause a problem of reduced rigidity of the beam portion 115. According to a preferred embodiment of the present invention, since the beam portions 115 are spaced apart and divided by the second gap S2 in the thickness direction (±z direction), the pin force can be reduced without reducing the length dimension of the beam portion 115 in the width direction (±x direction). In other words, the pin force can be reduced while maintaining the strength of the beam portion 115.

Additionally, according to an embodiment of the present invention, by arranging multiple beam portions 115 with smaller cross-sectional areas in an array instead of a single beam portion with a large cross-sectional area, the pin force can be reduced while maintaining the strength of the beam portion 115, making it possible to further shorten the length of the beam portion 115 compared to the prior art. As a result, the current path is shortened, making the electrical connector 100 according to a preferred embodiment of the present invention more effectively used for testing high-frequency inspection objects for AI and 5G applications.

### Electrical Connector 100 According to a Modification of the First Embodiment

Next, an electrical connector 100 according to a modification of the first embodiment of the present invention will be described. However, the modifications described below will focus on the characteristic components compared to the first embodiment, and the same or similar components as the first embodiment will be used in the modifications, and their descriptions will be omitted as much as possible.

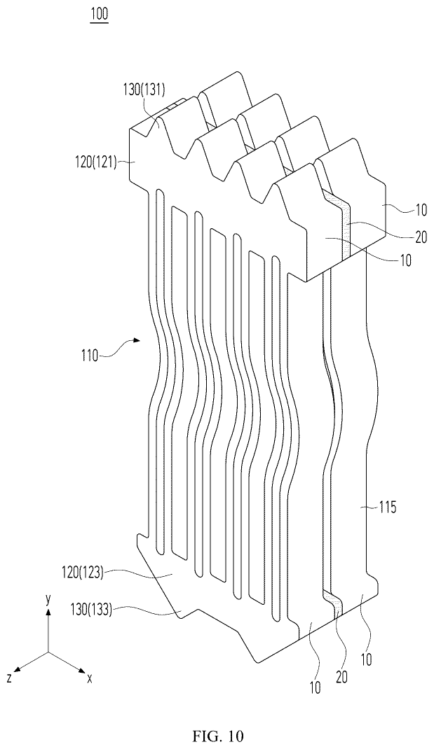

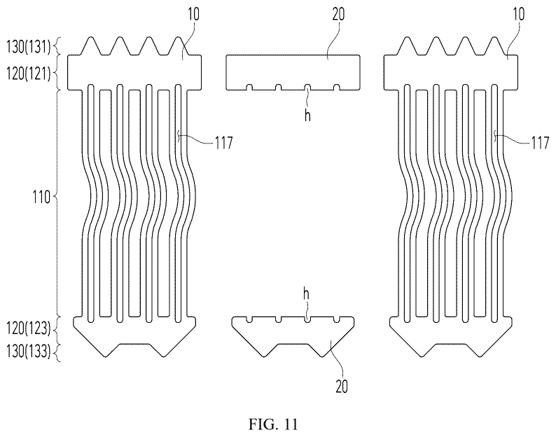

FIG. 10 is a perspective view of an electrical connector 100 according to a modification of the first embodiment, and FIG. 11 is an exploded view of an electrical connector 100 according to a modification of the first embodiment.

The modification of the first embodiment differs in the number of the first metal layer 10 and the second metal layer 20 and the thickness configuration of the first metal layer 10 compared to the first embodiment, while the other configurations are the same.

The electrical connector 100 includes a deformation portion array 110 and a connecting portion 120.

The deformation portion array 110 includes multiple beam portions 115 that extend in the length direction (±y direction) and are elastically deformable. The beam portions 115 are spaced apart in the width direction (±x direction) and the thickness direction (±z direction) to form the deformation portion array 110. The beam portions 115 are spaced apart in the width direction (±x direction). Additionally, the beam portions 115 are spaced apart in the thickness direction (±z direction) perpendicular to the width direction (±x direction).

The connecting portion 120 connects the beam portions 115 of the deformation portion array 110. Multiple beam portions 115 are connected to a single connecting portion 120. Multiple beam portions 115 provided in a bundled form are connected to the connecting portion 120 while being spaced apart from each other and integrated. The connecting portion 120 includes an upper connecting portion 121 provided on the upper side of the deformation portion array 110 and a lower connecting portion 123 provided on the lower side of the deformation portion array 110.

The tip portion 130 includes an upper tip portion 131 provided on the upper side of the upper connecting portion 121 and a lower tip portion 133 provided on the lower side of the lower connecting portion 123.

The electrical connector 100 includes a first metal layer 10 and a second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. Two first metal layers 10 and one second metal layer 20 are provided.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20, so each is spaced apart from each other in the thickness direction (±z direction). On the other hand, the lower tip portion 133 is provided with the first metal layer 10 and the second metal layer 20 of the lower connecting portion 123, and the first metal layer 10 and the second metal layer 20 are stacked in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deformed by an external force applied in the length direction.

The second metal layer 20 is provided in the upper connecting portion 121 and the lower connecting portion 123. A concave groove h is formed in the lower part of the second metal layer 20 provided in the upper connecting portion 121, and a concave groove h is formed in the upper part of the second metal layer 20 provided in the lower connecting portion 123. The position of the concave groove h corresponds to the end position of the slit 117.

### Electrical Connector 100 According to the Second Embodiment

Next, a second embodiment of the electrical connector 100 according to the present invention will be described. However, the second embodiment described below will be described focusing on characteristic components compared to the first embodiment, and the same or similar components as the first embodiment will be used in the configuration of the second embodiment, and the description thereof will be omitted as much as possible.

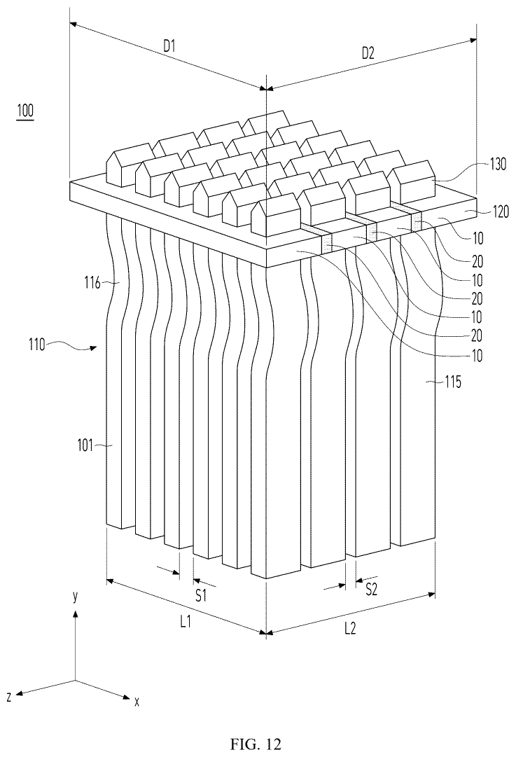

FIG. 12 is a perspective view of an electrical connector 100 according to a preferred second embodiment of the present invention.

The electrical connector 100 includes a deformation portion array 110 and a connecting portion 120.

The deformation portion array 110 includes a plurality of beam portions 115 that extend in the length direction (±y direction) and are elastically deformed. Each beam portion 115 extends in the length direction (±y direction) and has a bent portion 116 formed in the middle part. Each beam portion 115 is elastically deformed by an external force applied in the length direction (±y direction).

The cross-section of the beam portion 115 in the x-z plane is rectangular.

The beam portions 115 are spaced apart in the width direction (±x direction) and are provided in plurality. The plurality of beam portions 115 are spaced apart from each other by a first spacing gap S1 in the width direction (±x direction). In addition, the beam portions 115 are spaced apart in the thickness direction (±z direction) perpendicular to the width direction (±x direction) and are provided in plurality. The plurality of beam portions 115 are spaced apart from each other by a second spacing gap S2 in the thickness direction (±z direction).

The deformation portion array 110 shown in FIG. 12 includes a plurality of beam portions 115 spaced apart from each other by a first spacing gap S1 in the width direction (±x direction) and spaced apart from each other by a second spacing gap S2 in the thickness direction (±z direction) perpendicular to the width direction (±x direction). The sizes of the first spacing gap S1 and the second spacing gap S2 may be the same or different.

The length dimension of each beam portion 115 in the width direction (±x direction) is smaller than the length dimension in the thickness direction (±z direction), and each beam portion 115 has a bent portion 116 bent in the same direction, so it is more easily elastically deformed when subjected to compressive force in the length direction (±y direction).

The connecting portion 120 connects the beam portions 115 of the deformation portion array 110. A plurality of beam portions 115 are connected to one connecting portion 120. The plurality of beam portions 115 provided in a bundle form are connected to the connecting portion 120 while being spaced apart from each other and integrated.

The deformation portion array 110 has a length dimension L1 in the width direction (±x direction) and a length dimension L2 in the thickness direction (±z direction). In addition, the connecting portion 120 has a length dimension D1 in the width direction (±x direction) and a length dimension D2 in the thickness direction (±z direction).

The length dimension D1 of the connecting portion 120 in the width direction (±x direction) is larger than the length dimension L1 of the deformation portion array 110 in the width direction (±x direction). Meanwhile, the length dimension D2 of the connecting portion 120 in the thickness direction (±z direction) is larger than the length dimension L2 of the deformation portion array 110 in the thickness direction (±z direction). As a result, the length dimension D1 of the connecting portion 120 in the width direction (±x direction) is larger than the length dimension L1 of the deformation portion array 110 in the width direction (±x direction), and the length dimension D2 of the connecting portion 120 in the thickness direction (±z direction) is larger than the length dimension L2 of the deformation portion array 110 in the thickness direction (±z direction).

An upper tip portion 130 is provided on the upper part of the connecting portion 120. In other words, the tip portion 130 is provided on the upper part of the connecting portion 120.

The tip portion 130 is provided in plurality, spaced apart in the width direction (±x direction). Meanwhile, the tip portion 130 is provided in plurality, spaced apart in the thickness direction (±z direction). Therefore, the tip portion 130 is provided in plurality, spaced apart in the width direction (±x direction) and spaced apart in the thickness direction (±z direction). Each tip portion 130 can be provided in alignment with the length direction of each beam portion 115 corresponding to each beam portion 115.

The tip portion 130 includes a base portion with a constant cross-sectional area connected to the connecting portion 120 and a needle portion with a smaller cross-sectional area than the base portion located above the base portion. The needle portion is the part that contacts the external terminal 21 of the object to be inspected 20, and the base portion is the part that secures the rigidity of the needle portion.

The spacing distance of the tip portions 130 in the width direction (±x direction) is the same as the spacing distance of the beam portions 115 in the width direction (±x direction), and the spacing distance of the tip portions 130 in the thickness direction (±z direction) is the same as the spacing distance of the beam portions 115 in the thickness direction (±z direction).

The electrical connector 100 comprises a plurality of unit needle pins 101 and at least one connecting portion 120 that connects the plurality of unit needle pins 101. The unit needle pin 101 extends in the length direction (±y direction) and includes a beam portion 115 that is elastically deformed and a tip portion 130, and the adjacent unit needle pins 101 are bundled in a spaced-apart manner through the connecting portion 120 provided between the beam portion 115 and the tip portion 130.

The connecting portion 120 fixes the plurality of unit needles 101 in a spaced-apart manner and allows the plurality of unit needles 101 to move together. The connecting portion 120 is formed in the width direction (±x direction) and/or the thickness direction (±y direction) perpendicular to the length direction (±x direction) of the unit needle pin 101, performing the function of spacing and fixing the plurality of unit needle pins 101, and at least one such connecting portion 120 can be provided.

The electrical connector 100 comprises a first metal layer 10 and a second metal layer 20.

The first metal layer 10 is continuously formed in the length direction (±y direction) to constitute the upper tip portion 131, the connecting portion 120, and the beam portion 151, and the second metal layer 20 constitutes the connecting portion 120.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 can be provided in an even number, and the second metal layer 20 can be provided in an odd number. For example, as shown in the figure, four first metal layers 10 can be provided in the thickness direction (±z direction), and three second metal layers 20 can be provided. However, the number of such stacks is not limited to this.

The tip portion 130 is not provided with the second metal layer 20, so each is spaced apart from each other in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deformed by an external force applied in the length direction. The second spacing gap S2 spaced apart in the thickness direction (±z direction) of the beam portion 115 is the same as the thickness of the second metal layer 20 provided in the connecting portion 120.

The beam portion 115, the tip portion 130, and the connecting portion 120 provided between the beam portion 115 and the tip portion 130 consist of the first metal layer 10, so when the electrical connector 100 is elastically deformed by compressive force, it can maintain high strength, and the connecting portion 120 consists of the first metal layer 10 and the second metal layer 20, so the electrical conductivity of the connecting portion 120 can be improved.

### Electrical Connector 100 According to the Third Embodiment

Next, a third embodiment of the electrical connector 100 according to the present invention will be described. However, the third embodiment described below will be described focusing on characteristic components compared to the second embodiment, and the same or similar components as the second embodiment will be used in the configuration of the third embodiment, and the description thereof will be omitted as much as possible.

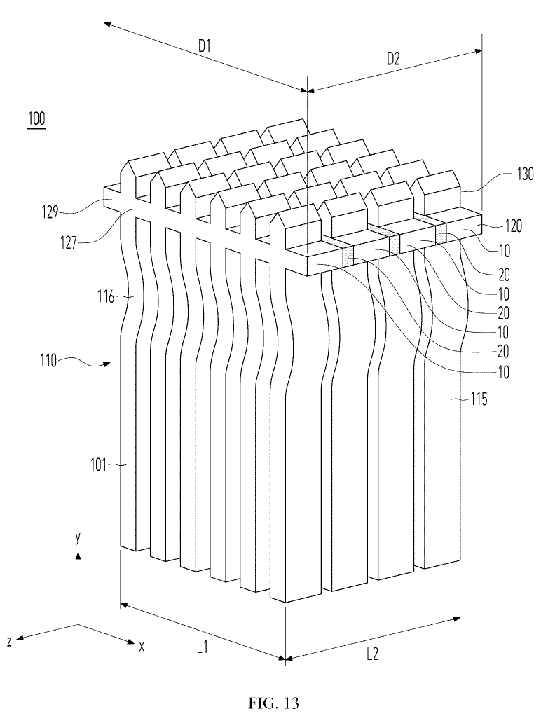

FIG. 13 is a perspective view of an electrical connector 100 according to a preferred third embodiment of the present invention.

The electrical connector 100 according to the third embodiment comprises a plurality of unit needle pins 101 spaced apart from each other and a connecting portion 120 that connects them. The electrical connector 100 comprises a plurality of unit needle pins 101 connected to each other by the connecting portion 120, and each beam portion 115 and tip portion 130 are provided in a spaced-apart form.

The deformation portion array 110 has a length dimension L1 in the width direction (±x direction) and a length dimension L2 in the thickness direction (±z direction). In addition, the connecting portion 120 has a length dimension D1 in the width direction (±x direction) and a length dimension D2 in the thickness direction (±z direction).

The third embodiment differs from the second embodiment in that the length dimension D1 of the connecting portion 120 in the width direction (±x direction) is larger than the length dimension L1 of the deformation portion array 110 in the width direction (±x direction), and the length dimension D2 of the connecting portion 120 in the thickness direction (±z direction) is the same as the length dimension L2 of the deformation portion array 110 in the thickness direction (±z direction). In other words, the connecting portion 120 of the third embodiment includes an inner connecting portion 127 and an outer connecting portion 129, but the outer connecting portion 129 is provided only in the width direction (±x direction) and not in the thickness direction (±z direction), which is different from the first embodiment, while the rest of the configuration is the same.

The electrical connector 100 comprises a first metal layer 10 and a second metal layer 20.

The first metal layer 10 is continuously formed in the length direction (±y direction) to constitute the upper tip portion 131, the connecting portion 120, and the beam portion 151, and the second metal layer 20 constitutes the connecting portion 120.

The connecting portion 120 is provided by stacking the first metal layer 10 and the second metal layer 20 in the thickness direction (±z direction). The second metal layer 20 provided in the connecting portion 120 is provided between the adjacent first metal layers 10. Four first metal layers 10 and three second metal layer 20 are provided.

The beam portion 115 consists of the first metal layer 10 and is spaced apart in the thickness direction (±z direction) without the second metal layer 20 between the first metal layers 10, so that the first metal layers 10 are spaced apart in the thickness direction (±z direction) and elastically deformed by an external force applied in the length direction.

### Electrical Connector 100 According to the Fourth Embodiment

Next, the fourth embodiment of the electrical connector 100 according to the present invention will be described. However, the fourth embodiment described below will be described focusing on the characteristic components compared to the third embodiment, and the same or similar components as the fourth embodiment will be used in the configuration of the fourth embodiment, and the description thereof will be omitted as much as possible.

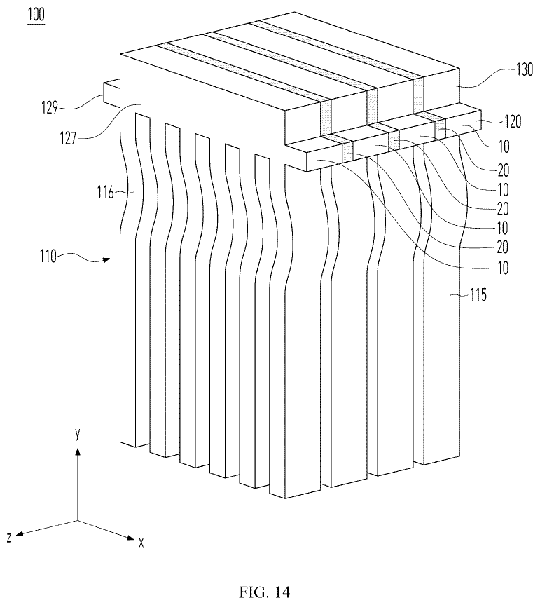

FIG. 14 is a perspective view of an electrical connector 100 according to a preferred fourth embodiment of the present invention.

A tip portion 130 is provided on the upper part of the connecting portion 120.

The fourth embodiment differs from the third embodiment in that only one upper tip portion 130 is provided, and the rest of the configuration is the same as that of the third embodiment.

The upper connecting portion 120 and the upper tip portion 130 are provided by stacking the first metal layer 10 and the second metal layer 20 in the thickness direction (±z direction). The second metal layer 20 provided in the upper connecting portion 120 and the upper tip portion 130 is provided between the adjacent first metal layers 10. The first metal layer 10 and the second metal layer 20 of the upper connecting portion 120 are extended and provided in the upper tip portion 130. An even number of first metal layers 10 and an odd number of second metal layers 20 may be provided. For example, as shown in the figure, four first metal layers 10 may be provided in the thickness direction (±z direction), and three second metal layers 20 may be provided. However, the number of such stacks is not limited thereto.

The beam portion 115 consists of the first metal layer 10 and is spaced apart in the thickness direction (±z direction) without the second metal layer 20 between the first metal layers 10, so that the first metal layers 10 are spaced apart in the thickness direction (±z direction) and elastically deformed by an external force applied in the length direction.

### Electrical Connector 100 According to the Fifth Embodiment

Next, the fifth embodiment of the electrical connector 100 according to the present invention will be described. However, the fifth embodiment described below will be described focusing on the characteristic components compared to the fourth embodiment, and the same or similar components as the fourth embodiment will be used in the configuration of the fifth embodiment, and the description thereof will be omitted as much as possible.

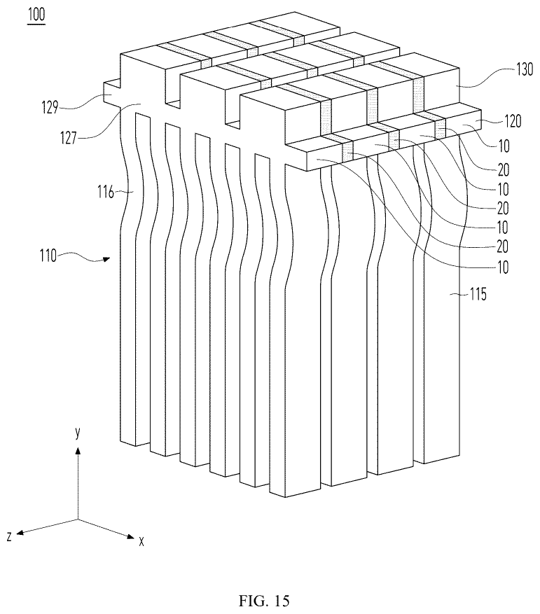

FIG. 15 is a perspective view of an electrical connector 100 according to a preferred fifth embodiment of the present invention.

The fifth embodiment differs from the fourth embodiment in the configuration of the tip portion 130, and the rest of the configuration is the same as that of the fourth embodiment. More specifically, the tip portion 130 in the fifth embodiment is provided with a plurality of tip portions 130 spaced apart only in the width direction (±x direction), which is different from the configuration of the fourth embodiment in which one tip portion 130 is provided.

### Electrical Connector 100 According to the Sixth Embodiment

Next, the sixth embodiment of the electrical connector 100 according to the present invention will be described. However, the sixth embodiment described below will be described focusing on the characteristic components compared to the third embodiment, and the same or similar components as the third embodiment will be used in the configuration of the sixth embodiment, and the description thereof will be omitted as much as possible.

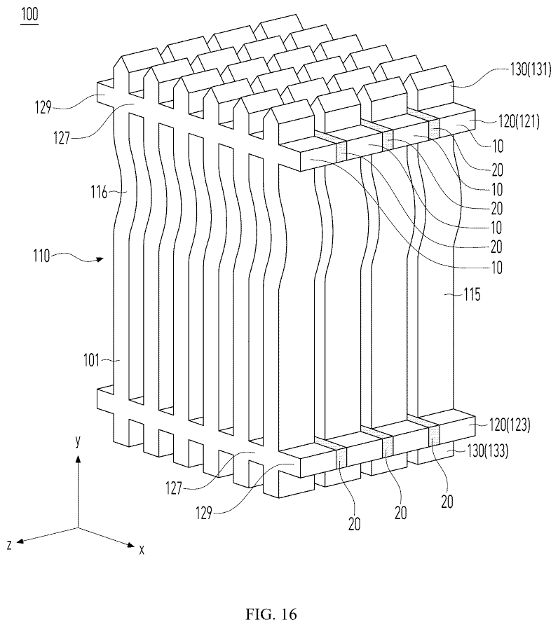

FIG. 16 is a perspective view of an electrical connector 100 according to a preferred sixth embodiment of the present invention.

The electrical connector 100 according to the sixth embodiment comprises a plurality of unit needle pins 101 spaced apart from each other and a connecting portion 120 connecting them. The connecting portion 120 includes an upper connecting portion 121 and a lower connecting portion 123. The electrical connector 100 is configured such that a plurality of unit needle pins 101 are connected to each other by the connecting portion 120, and each beam portion 115 and tip portion 130 are spaced apart from each other.

The sixth embodiment differs from the third embodiment in that it includes an upper connecting portion 121 provided on the upper side of the deformation portion array 110 and a lower connecting portion 123 provided on the lower side of the deformation portion array 110, and the sixth embodiment differs from the third embodiment in that it includes an upper tip portion 131 provided on the upper side of the upper connecting portion 121 and a lower tip portion 133 provided on the lower side of the lower connecting portion 123.

The electrical connector 100 is configured such that a plurality of unit needle pins 101 are connected to each other by the upper connecting portion 121 and the lower connecting portion 123, each beam portion 115 is spaced apart from each other, each upper tip portion 131 is spaced apart from each other, and each lower tip portion 133 is spaced apart from each other.

The upper connecting portion 121 bundles the upper parts of a plurality of beam portions 115 provided in a bundle form, and the lower connecting portion 123 also bundles the lower parts of a plurality of beam portions 115 provided in a bundle form.

The outer connecting portion 129 of the upper connecting portion 121 is provided only in the width direction (±x direction) and not in the thickness direction (±z direction), and the outer connecting portion 129 of the lower connecting portion 123 is also provided only in the width direction (±x direction) and not in the thickness direction (±z direction).

The upper tip portion 131 is provided with a plurality of tip portions spaced apart in the width direction (±x direction). Meanwhile, the upper tip portion 131 is provided with a plurality of tip portions spaced apart in the thickness direction (±z direction). Therefore, the upper tip portion 131 is provided with a plurality of tip portions spaced apart in the width direction (±x direction) and a plurality of tip portions spaced apart in the thickness direction (±z direction).

Each upper tip portion 131 may be provided in the extension line of each beam portion 115 in the length direction corresponding to each beam portion 115.

The spacing distance of the upper tip portions 131 in the width direction (±x direction) is the same as the spacing distance of the beam portions 115 in the width direction (±x direction), and the spacing distance of the upper tip portions 131 in the thickness direction (±z direction) is the same as the spacing distance of the beam portions 115 in the thickness direction (±z direction).

The lower tip portion 133 is provided with a plurality of tip portions spaced apart in the width direction (±x direction). Meanwhile, the lower tip portion 133 is provided with a plurality of tip portions spaced apart in the thickness direction (±z direction). Therefore, the lower tip portion 130 is provided with a plurality of tip portions spaced apart in the width direction (±x direction) and a plurality of tip portions spaced apart in the thickness direction (±z direction).

Each lower tip portion 133 may be provided in the extension line of each beam portion 115 in the length direction corresponding to each beam portion 115.

The spacing distance of the lower tip portions 133 in the width direction (±x direction) is the same as the spacing distance of the beam portions 115 in the width direction (±x direction), and the spacing distance of the lower tip portions 133 in the thickness direction (±z direction) is the same as the spacing distance of the beam portions 115 in the thickness direction (±z direction).

The electrical connector 100 comprises a first metal layer 10 and a second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121 and the lower connecting portion 123.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20 such that each is spaced apart from each other in the thickness direction (±z direction).

The lower tip portion 133 is also not provided with the second metal layer 20 such that each is spaced apart from each other in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deform by an external force applied in the length direction.

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by an applied force, it can maintain high strength, and the upper connecting portion 121 and the lower connecting portion 123 consist of the first metal layer 10 and the second metal layer 20, thereby improving the electrical conductivity of the connecting portion 120.

### Electrical Connector 100 According to the Seventh Embodiment

Next, the seventh embodiment of the electrical connector 100 according to the present invention will be described. However, the seventh embodiment described below will be explained focusing on the characteristic components compared to the sixth embodiment, and the same or similar components as the sixth embodiment will be used in the configuration of the seventh embodiment, and their description will be omitted as much as possible.

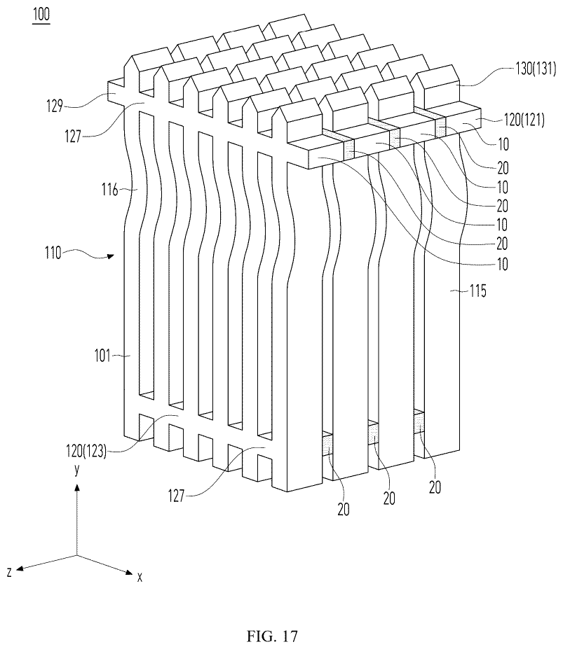

FIG. 17 is a perspective view of the electrical connector 100 according to the preferred seventh embodiment of the present invention.

The electrical connector 100 according to the seventh embodiment comprises a plurality of unit needle pins 101 arranged spaced apart from each other and a connecting portion 120 connecting them. The connecting portion 120 includes an upper connecting portion 121 and a lower connecting portion 123. The electrical connector 100 has a plurality of unit needle pins 101 connected by the connecting portion 120, and each beam portion 115 and tip portion 130 are provided in a spaced-apart form.

The seventh embodiment differs from the sixth embodiment in that the lower connecting portion 123 is provided with only the inner connecting portion 127 and not the outer connecting portion 129, and the rest of the configuration is the same.

The electrical connector 100 includes the first metal layer 10 and the second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121 and the lower connecting portion 123.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20, so each is spaced apart from each other in the thickness direction (±z direction). The lower tip portion 133 is also not provided with the second metal layer 20, so each is spaced apart from each other in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deform by an external force applied in the length direction.

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by an applied force, it can maintain high strength, and the upper connecting portion 121 and the lower connecting portion 123 consist of the first metal layer 10 and the second metal layer 20, thereby improving the electrical conductivity of the connecting portion 120.

### Electrical Connector 100 According to the Eighth Embodiment

Next, the eighth embodiment of the electrical connector 100 according to the present invention will be described. However, the eighth embodiment described below will be explained focusing on the characteristic components compared to the seventh embodiment, and the same or similar components as the seventh embodiment will be used in the configuration of the eighth embodiment, and their description will be omitted as much as possible.

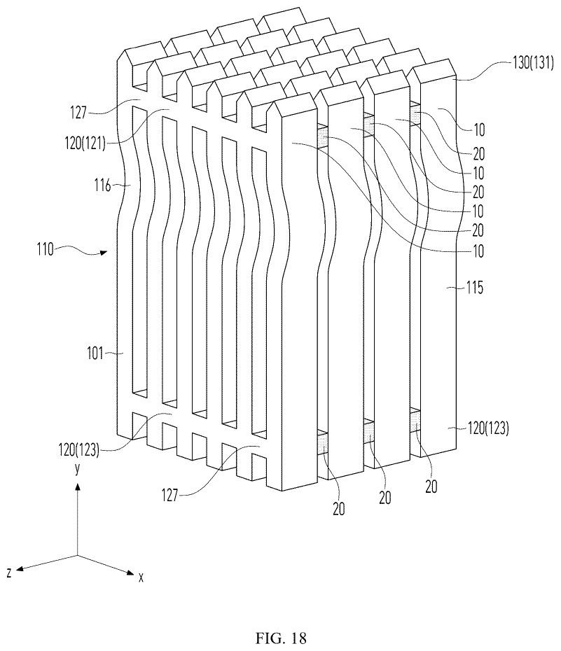

FIG. 18 is a perspective view of the electrical connector 100 according to the preferred eighth embodiment of the present invention.

The electrical connector 100 according to the eighth embodiment comprises a plurality of unit needle pins 101 arranged spaced apart from each other and a connecting portion 120 connecting them. The connecting portion 120 includes an upper connecting portion 121 and a lower connecting portion 123. The electrical connector 100 has a plurality of unit needle pins 101 connected by the connecting portion 120, and each beam portion 115 and tip portion 130 are provided in a spaced-apart form.

The eighth embodiment differs from the seventh embodiment in that the upper connecting portion 121 is provided with only the inner connecting portion 127 and not the outer connecting portion 129, and the rest of the configuration is the same.

The electrical connector 100 includes the first metal layer 10 and the second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121 and the lower connecting portion 123.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20, so each is spaced apart from each other in the thickness direction (±z direction). The lower tip portion 133 is also not provided with the second metal layer 20, so each is spaced apart from each other in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deform by an external force applied in the length direction.

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by an applied force, it can maintain high strength, and the upper connecting portion 121 and the lower connecting portion 123 consist of the first metal layer 10 and the second metal layer 20, thereby improving the electrical conductivity of the connecting portion 120.

### Electrical Connector 100 According to the Ninth Embodiment

Next, the ninth embodiment of the electrical connector 100 according to the present invention will be described. However, the ninth embodiment described below will be explained focusing on the characteristic components compared to the seventh embodiment, and the same or similar components as the seventh embodiment will be used in the configuration of the ninth embodiment, and their description will be omitted as much as possible.

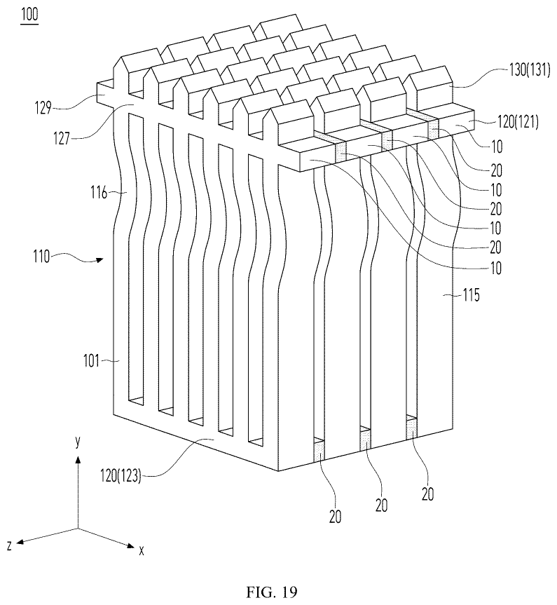

FIG. 19 is a perspective view of the electrical connector 100 according to the preferred ninth embodiment of the present invention.

The electrical connector 100 according to the ninth embodiment comprises a plurality of unit needle pins 101 arranged spaced apart from each other and a connecting portion 120 connecting them. The connecting portion 120 includes an upper connecting portion 121 and a lower connecting portion 123. The electrical connector 100 has a plurality of unit needle pins 101 connected by the connecting portion 120, and each beam portion 115 and tip portion 130 are provided in a spaced-apart form.

The ninth embodiment differs from the seventh embodiment in that no separate individual tip portion is provided at the lower part of the lower connecting portion 123, whereas the seventh embodiment has an individual lower tip portion 133, and the rest of the configuration is the same.

The electrical connector 100 includes the first metal layer 10 and the second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121 and the lower connecting portion 123.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The upper tip portion 131 is not provided with the second metal layer 20, so each is spaced apart from each other in the thickness direction (±z direction). The lower tip portion 133 is also not provided with the second metal layer 20, so each is spaced apart from each other in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deformed by an external force applied in the length direction.

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by a pressing force, it can maintain high strength, and the upper connecting portion 121 and the lower connecting portion 123 consist of the first metal layer 10 and the second metal layer 20, so the electrical conductivity of the connecting portion 120 can be improved.

### Electrical Connector 100 According to the Tenth Embodiment

Next, the tenth embodiment of the electrical connector 100 according to the present invention will be described. However, the tenth embodiment described below will be described focusing on the characteristic components compared to the third embodiment, and the same or similar components as the third embodiment will be used in the configuration of the tenth embodiment, and the description thereof will be omitted as much as possible.

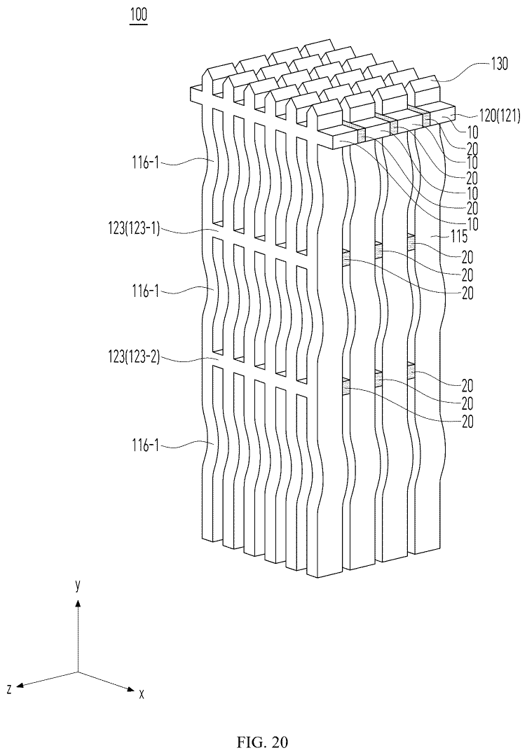

FIG. 20 is a perspective view of an electrical connector 100 according to a preferred tenth embodiment of the present invention.

The electrical connector 100 according to the tenth embodiment comprises a plurality of unit needle pins 101 arranged spaced apart from each other and a connecting portion 120 connecting them. The connecting portion 120 includes an upper connecting portion 121, a first lower connecting portion 123-1, and a second lower connecting portion 123-2. The electrical connector 100 is configured such that the plurality of unit needle pins 101 are connected to each other by the connecting portion 120, and each beam portion 115 and tip portion 130 are provided in a spaced-apart form.

The third embodiment differs in that it includes only one connecting portion 120, whereas the tenth embodiment includes three connecting portions 120. In addition, the third embodiment has only one deformation section in the beam portion 115, whereas the tenth embodiment has a plurality of deformation sections.

The connecting portion 120 of the tenth embodiment includes an upper connecting portion 121 and a lower connecting portion 123, wherein the lower connecting portion 123 includes a first lower connecting portion 123-1 located below the upper connecting portion 121 and a second lower connecting portion 123-2 located below the first lower connecting portion 123-1.

The upper connecting portion 121 includes an inner connecting portion 127 and an outer connecting portion 129, but the first lower connecting portion 123-1 and the second lower connecting portion 123-2 include only the inner connecting portion 127 and do not include the outer connecting portion 129.

A first bending portion 116-1 is provided in the beam portion 115 between the upper connecting portion 121 and the first lower connecting portion 123-1, a second bending portion 116-2 is provided in the beam portion 115 between the first lower connecting portion 123-1 and the second lower connecting portion 123-2, and a third bending portion 116-3 is provided below the second lower connecting portion 123-2.

Meanwhile, in the tenth embodiment, the connecting portion 120 is illustrated as having three, but it is not limited thereto, and the configuration of the tenth embodiment also includes having four or more connecting portions 120.

The electrical connector 100 comprises the first metal layer 10 and the second metal layer 20.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121, the first lower connecting portion 123-1 and the second lower connecting portion 123-2.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deformed by an external force applied in the length direction.

### Electrical Connector 100 According to the Eleventh Embodiment

Next, the eleventh embodiment of the electrical connector 100 according to the present invention will be described. However, the eleventh embodiment described below will be described focusing on the characteristic components compared to the second embodiment, and the same or similar components as the second embodiment will be used in the configuration of the eleventh embodiment, and the description thereof will be omitted as much as possible.

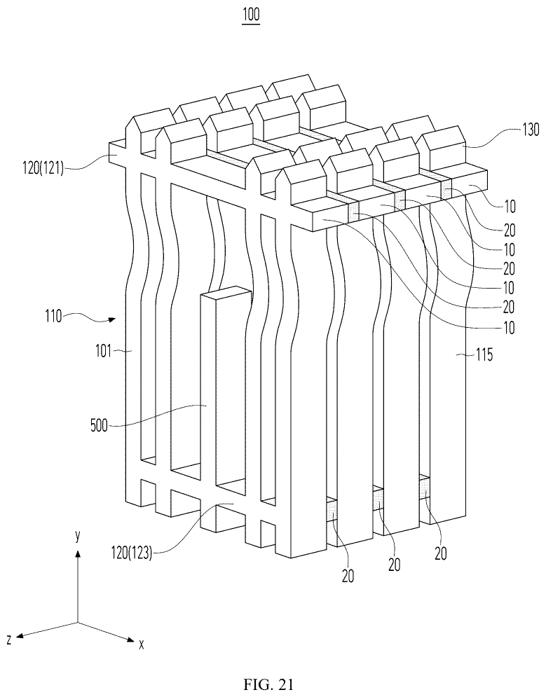

FIG. 21 is a perspective view of an electrical connector 100 according to a preferred eleventh embodiment of the present invention.

The electrical connector 100 according to the eleventh embodiment comprises a plurality of unit needle pins 101 arranged spaced apart from each other and a connecting portion 120 connecting them. The connecting portion 120 includes an upper connecting portion 121 and a lower connecting portion 123. The electrical connector 100 is configured such that the plurality of unit needle pins 101 are connected to each other by the connecting portion 120, and each beam portion 115 and tip portion 130 are provided in a spaced-apart form.

The electrical connector 100 of the eleventh embodiment differs from the configuration of the second embodiment in that it includes at least one stopper 500 to prevent excessive deformation of the deformation portion array 110. The stopper 500 is provided in a position where it can contact the connecting portion 120 when the deformation portion array 110 is excessively compressed. At least one stopper 500 is provided.

The stopper 500 is provided extending in the length direction (±y direction) from the lower connecting portion 123 between the upper connecting portion 121 and the lower connecting portion 123. The lower part of the stopper 500 is connected to the lower connecting portion 123, and the upper part of the stopper 500 is provided as a free end.

The deformation portion array 110 is compressed and deformed by an external force and may be unintentionally excessively compressed. Such excessive compression deformation can cause damage to the beam portion 115 of the deformation portion array 110. However, according to the eleventh embodiment, even if the deformation portion array 110 is excessively compressed, the upper connecting portion 121 descends and contacts the stopper 500, thereby preventing further compression deformation of the deformation portion array 110 and preventing damage to the beam portion 115.

The stopper 500 can be provided between the beam portions 115. Preferably, it can be located in the center of the deformation portion array 110 in the width direction (±x direction). However, the position of the stopper 500 is not limited to this, and it can be located in any position that can prevent excessive deformation of the deformation portion array 110.

In the drawings, only one stopper 500 is shown, but it is also possible to provide a plurality of stoppers 500 spaced apart.

The electrical connector 100 comprises the first metal layer 10 and the second metal layer 20.

The first metal layer 10 is continuously formed in the length direction (±y direction) to constitute the connecting portion 120 and the beam portion 115, and the second metal layer 20 does not constitute the beam portion 115 but constitutes the connecting portion 120. More specifically, the first metal layer 10 is continuously formed in the length direction (±y direction) to constitute the upper connecting portion 121, the beam portion 151, and the lower connecting portion 123, and the second metal layer 20 is discontinuously formed in the length direction (±y direction) to constitute the upper connecting portion 121 and the lower connecting portion 133.

The connecting portion 120 is provided by stacking the first metal layer 10 and the second metal layer 20 in the thickness direction (±z direction). The second metal layer 20 provided in the connecting portion 120 is provided between the adjacent first metal layers 10. The first metal layer 10 is provided with four layers, and the second metal layer 20 is provided with three layers at each of the upper connecting portion 121 and the lower connecting portion 123.

The upper connecting portion 121 is provided by stacking the first metal layer 10 and the second metal layer 20 in the thickness direction (±z direction), and the lower connecting portion 123 is also provided by stacking the first metal layer 10 and the second metal layer 20 in the thickness direction (±z direction).

The beam portion 115 consists of the first metal layer 10, and the second metal layer 20 is not provided between the first metal layers 10 in the thickness direction (±z direction), so the first metal layers 10 are spaced apart from each other in the thickness direction (±z direction) and elastically deformed by an external force applied in the length direction.

The beam portion 115, the upper tip portion 131, the lower tip portion 133, the upper connecting portion 121 provided between the beam portion 115 and the upper tip portion 131, and the lower connecting portion 123 provided between the beam portion 115 and the lower tip portion 133 consist of the first metal layer 10, so when the electrical connector 100 is elastically deformed by a pressing force, it can maintain high strength, and the upper connecting portion 121 and the lower connecting portion 123 consist of the first metal layer 10 and the second metal layer 20, so the electrical conductivity of the connecting portion 120 can be improved.

As described above, the preferred embodiments of the present invention have been described with reference to the accompanying drawings, but those skilled in the art can make various modifications or changes to the present invention without departing from the spirit and scope of the invention as set forth in the following claims.

What is claimed is:

1. An electrical connector including a first metal layer and a second metal layer, the electrical connector comprising:
a plurality of beam portions consisting of the first metal layer, wherein the second metal layer is not provided between the first metal layers in the thickness direction such that the first metal layers are spaced apart from each other in the thickness direction and elastically deformed by an external force applied in the length direction; and
a connecting portion in which the first metal layer and the second metal layer are stacked in the thickness direction and which connects the plurality of beam portions.

2. The electrical connector of claim 1, wherein
the metal constituting the first metal layer is selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy or nickel-phosphorus (NiPh) alloy, nickel-manganese (NiMn), nickel-cobalt (NiCo) or nickel-tungsten (NiW) alloy, and
the metal constituting the second metal layer is selected from copper (Cu), silver (Ag), gold (Au) or alloys thereof.

3. The electrical connector of claim 1, wherein
the first metal layer is continuously formed in the length direction to constitute the connecting portion and the beam portion, and the second metal layer does not constitute the beam portion but constitutes the connecting portion 120.

4. The electrical connector of claim 1, wherein
the spacing distance of the beam portions in the thickness direction is the same as the thickness of the second metal layer provided in the connecting portion.

5. The electrical connector of claim 1, wherein
the beam portions are spaced apart in the width direction and the thickness direction to constitute a deformation portion array, and
the connecting portion connects the beam portions of the deformation portion array.

6. The electrical connector of claim 5, wherein
the connecting portion includes an upper connecting portion provided on the upper side of the deformation portion array, and
the length dimension of the upper connecting portion in the width direction is larger than the length dimension of the deformation portion array in the width direction, and the length dimension of the upper connecting portion in the thickness direction is the same as the length dimension of the deformation portion array in the thickness direction.

7. The electrical connector of claim 5, wherein
the connecting portion includes an upper connecting portion provided on the upper side of the deformation portion array, and
the upper connecting portion is provided by alternately stacking the first metal layer and the second metal layer in the thickness direction.

8. The electrical connector of claim 7, wherein
the lower part of the protruding portion of the upper connecting portion is a portion overlapping the upper surface of the guide plate, and the first metal layer is extended further downward than the second metal layer so that the second metal layer does not protrude from the lower part of the upper connecting portion.

9. The electrical connector of claim 5, wherein
the connecting portion includes an upper connecting portion provided on the upper side of the deformation portion array,
the electrical connector includes an upper tip portion provided on the upper side of the upper connecting portion, and
the upper tip portion is not provided with the second metal layer such that each is spaced apart from each other in the thickness direction.

10. The electrical connector of claim 5, wherein
the connecting portion includes an upper connecting portion provided on the upper side of the deformation portion array,
the electrical connector includes an upper tip portion provided on the upper side of the upper connecting portion, and
the first metal layer and the second metal layer of the upper connecting portion are extended and provided in the upper tip portion.

11. The electrical connector of claim 5, wherein
the connecting portion includes a lower connecting portion provided on the upper side of the deformation portion array, and
the lower connecting portion is provided by stacking the first metal layer and the second metal layer in the thickness direction.

12. The electrical connector of claim 5, wherein
the connecting portion includes a lower connecting portion provided on the upper side of the deformation portion array,
the electrical connector includes a lower tip portion provided on the lower side of the lower connecting portion, and
the lower tip portion is not provided with the second metal layer such that each is spaced apart from each other in the thickness direction.

13. The electrical connector of claim 5, wherein
the connecting portion includes a lower connecting portion provided on the upper side of the deformation portion array,
the electrical connector includes a lower tip portion provided on the lower side of the lower connecting portion, and
the first metal layer and the second metal layer of the lower connecting portion are extended and provided in the lower tip portion.

14. The electrical connector of claim 1, wherein
a slit is provided between the beam portions in the width direction, and
the slit is recessed inward of the connecting portion, and the length of the slit in the length direction is longer than the length of the beam portion in the length direction.
